(19) United States
(12) Patent Application Publication
(10) Pub. No.: US 2011/0226301 A1
(43) Pub. Date: Sep. 22, 2011

(54) THERMOELECTRIC COLLECTION AND STORAGE OF SOLAR ENERGY

(76) Inventor: Dan Kershaw, Mesquite, NV (US)

(21) Appl. No.: 12/728,923

(22) Filed: Mar. 22, 2010

(51) Int. Cl. H01L 35/00

(52) U.S. Cl. 136/206

(57) ABSTRACT

A thermoelectric collector generates electricity from solar energy which may be stored or used for various applications. In general, the collector utilizes a high density thermopile to generate electricity. The thermoelectric collector may be configured to heat the high density thermopile at one end and cool another end to establish a thermal gradient. This temperature gradient generates electricity. The high density thermopile provides numerous advantages including a generally solid structure which lends itself to the creation of a thermal gradient, and ruggedness for outdoor applications. In addition, the stacked arrangement of the high density thermopile's components allows for high efficiency as well as easy maintenance and adjustability of electrical output capacity. Further, the high density thermopile may be shaped in various ways due to its novel configuration. In one embodiment, the high density thermopile may form a solar collector to direct heat towards itself.

### BACKGROUND OF THE INVENTION

1. Field of the Invention

The invention relates generally to the collection of solar energy and in particular to a method and apparatus for thermoelectric collection and storage of solar energy.

2. Related Art

Solar energy, while abundant and clean, has the drawback of being difficult to convert into usable energy such as electricity. For example, photovoltaic cells have been used to convert solar energy into electricity. Photovoltaic cells must be kept clean however, and are relatively inefficient. Solar energy may also be converted into electricity by utilizing its heat to power steam generators. This utilizes multiple conversions, from solar heat energy to mechanical energy and then to electricity. At each conversion point some energy is lost, reducing the efficiency of the overall system.

Solar energy may also be converted into electricity by the thermoelectric effect. Typically however, the thermoelectric effect generates small amounts of electricity, and is most often used to measure temperature, and not to generate electricity for use. The thermoelectric effect has been used to generate electricity from heat however, the heat source is generally a mechanical device or machinery which operates at very high temperatures. For example, it has been proposed that automobile exhaust heat be used to generate electricity to at least partially power a vehicle through the thermoelectric effect. This application of the thermoelectric effect relies upon a mechanical heat source which is not as abundant and clean as solar heat energy. In addition, the application of the thermoelectric effect in this manner typically generates little usable electricity.

From the discussion that follows, it will become apparent that the present invention addresses the deficiencies associated with the conversion of solar heat energy to electricity with the thermoelectric effect while providing numerous additional advantages and benefits not contemplated or possible with prior art constructions.

### SUMMARY OF THE INVENTION

A thermoelectric collector for generating electricity from solar energy is provided herein. The thermoelectric collector harnesses heat from the sun to generate electricity in a non-polluting manner. The electricity may be converted to hydrogen for storage for later use or used for other applications. The thermoelectric collector generally utilizes a high density thermopile which is efficient, reliable, and easily configurable for various electrical output capacities. Among the benefits described herein, the high density thermopile may be formed into various shapes to allow solar heat to be focused on a heated end of the high density thermopile by the thermopile itself.

In one embodiment, the thermoelectric collector comprises a high density thermopile, a solar concentrator configured to direct heat from the sun on the heated end of the high density thermopile, a cooling mechanism configured to transfer heat away from the cooled end of the high density thermopile with one or more coolants, and one or more electrical leads connected to one or more of the conductive materials. The electrical leads may conduct electricity generated by the high density thermopile for various applications. For example, an electrolysis tank, configured to generate hydrogen through electrolysis, may be powered by electricity from the one or more electrical leads.

The high density thermopile may have a heated end and a cooled end. In addition, the high density thermopile may comprise one or more planar dissimilar conductive materials and one or more planar insulating materials arranged in a stack to form a solid body. The one or more insulating materials may be staggered to form one or more electrical junctions at one end or alternating ends of the high density thermopile. One or more fasteners may be used to secure the one or more planar dissimilar conductive materials and one or more planar insulating materials at the heated end and the cooled end to form the one or more electrical junctions.

The cooling mechanism of the thermoelectric collector may be formed in various ways. For example, the cooling mechanism may comprise a heat exchanger configured to transfer heat from the cooled end of the high density thermopile. In addition, or alternatively, the cooling mechanism may comprise a quench ring at the cooled end of the high density thermopile configured to cool the cooled end with one or more coolants, and a heat exchanger configured to receive the one or more coolants from the quench ring. The heat exchanger absorbs heat from the coolants which cools the coolants and which in turn may be used to cool the cooled end of the high density thermopile.

It is noted that the heat exchanger itself may have various configurations. For instance, the heat exchanger may comprise an outer wall, one or more deflectors on an inner surface of the heat exchanger configured to direct the one or more coolants toward the outer wall to transfer heat from the one or more coolants to the heat exchanger, and one or more cooling fins on the outer wall, the one or more cooling fins configured to dissipate heat from the outer wall.

In one embodiment, the thermoelectric collector may comprise a high density thermopile, a parabolic solar concentrator configured to direct heat from the sun on the heated end of the high density thermopile, and one or more electrical leads connected to one or more of the one or more conductive materials, the one or more electrical leads configured to conduct electricity generated by the high density thermopile.

In this embodiment, the cooled end of the high density thermopile may have an increased surface area relative to the heated end to cool the cooled end of the high density thermopile. In addition or alternatively, the one or more dissimilar conductive materials of the high density thermopile may be used to form the solar concentrator. Such a solar concentrator may have a curved surface to direct heat from the sun on the heated end of the high density thermopile. One or more openings at the cooled end of the high density thermopile may be provided to help cool the cooled end of the high density thermopile.

In one embodiment, a cooling mechanism at the cooled end of the high density thermopile may be provided as well or instead of the one or more openings.

If energy storage is desired, the thermoelectric collector may include an electrolysis tank configured to generate hydrogen through electrolysis. Similar to the above, the electrolysis tank may be powered by electricity from the one or more electrical leads.

A method of solar energy collection is also provided herein. In one embodiment, the method comprises receiving heat at the heated end of a high density thermopile, creating a temperature differential between the heated end of the high density thermopile and the cooled end of the high density thermopile, and generating electricity with the temperature differential between the heated end and the cooled end of the high density thermopile. It is noted that the high density thermopile allows electricity to be generated efficiently and reliably, as will be described further below.

The method may also include directing heat from the sun on the heated end of the thermopile with a parabolic solar concentrator. Such a solar concentrator may be comprised of the one or more dissimilar conductive materials of the high density thermopile. For example, the one or more dissimilar conductive materials of the high density thermopile may fan out and curve to form the parabolic solar concentrator. The method may also include converting the generated electricity to hydrogen through electrolysis. This allows the energy collected according to the method to be stored.

Other systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE DRAWINGS

The components in the figures are not necessarily to scale, emphasis instead being placed upon illustrating the principles of the invention. In the figures, like reference numerals designate corresponding parts throughout the different views.

FIG. 1 is a block diagram illustrating an exemplary thermoelectric collector for storing energy as hydrogen;

FIG. 2A is a perspective view of an exemplary high density thermopile;

FIG. 2B is an exploded view of an exemplary high density thermopile;

FIG. 3 is a perspective view of an exemplary water cooled thermoelectric collector;

FIG. 4 is a top view of an exemplary quench ring for a thermoelectric collector;

FIG. 5 is a top view of an exemplary heat exchanger for a thermoelectric collector;

FIG. 6 is a perspective view of an exemplary air cooled thermoelectric collector;

FIG. 7 is a top view of an exemplary shaped high density thermopile; and

FIG. 8 is a perspective view of a portion of an exemplary solar collector formed with a high density thermopile.

### DETAILED DESCRIPTION OF THE PREFERRED EMBODIMENTS

In the following description, numerous specific details are set forth in order to provide a more thorough description of the present invention. It will be apparent, however, to one skilled in the art, that the present invention may be practiced without these specific details. In other instances, well-known features have not been described in detail so as not to obscure the invention.

In general, the thermoelectric collector herein converts solar heat energy into a storable form. The thermoelectric collector may utilize the thermoelectric effect, also known as the Peltier-Seebeck effect, to generate electricity directly with heat from the sun in one or more embodiments. As used herein, the term thermoelectric effect refers to the characteristic of dissimilar conductive materials, joined at an electrical junction, to generate electricity when a temperature difference or thermal gradient occurs along the conductive materials. As will be described below, the thermoelectric collector herein utilizes a novel high density thermopile to generate electricity from heat in one or more embodiments.

Electricity generated by the thermoelectric collector may be put to use or be stored for later use. This is highly advantageous because the energy generated by the thermoelectric collector comes from solar energy which is a non-polluting energy source and abundant. In addition, the thermoelectric collector allows solar energy to be used at night or when the sun is obscured by weather or other phenomena. This is because the thermoelectric collector may be configured to store the solar energy it collects so that the energy may be used when desired.

An exemplary thermoelectric collector will now be described with regard to FIG. 1. FIG. 1 is a block diagram illustrating various components of an exemplary thermoelectric collector 144. Of course, a thermoelectric collector 144 may comprise a subset of these components as well as components not illustrated by the exemplary embodiment.

As shown, the thermoelectric collector 144 comprises a solar concentrator 104 and thermoelectric generator 108. The solar concentrator 104 may be configured to gather solar energy and concentrate it to maximize its effects. For example, the solar concentrator 104 may be an optical device which focuses the sun's rays over a larger area onto a particular smaller area. In one embodiment, the solar concentrator 104 may be one or more lenses, a reflective parabolic dish or curved surface, or other reflective surface which focuses or concentrates the sun's rays onto a particular area. The concentrated energy may then be applied to the thermoelectric generator 108 to produce electricity.

In general, the thermoelectric generator 108 utilizes the thermoelectric effect to generate electricity from heat. In one or more embodiments, the thermoelectric generator 108 may comprise a heated end and a cooled end. The temperature gradient between these ends controls the amount of electricity that can be generated. Typically, the greater the difference in temperature between the heated end and the cooled end the more electricity can be generated.

The thermoelectric generator 108 herein, which will be described further below, has a novel configuration which is well suited for electricity generation with solar heat energy. In addition and as will be described further below, unlike traditional thermoelectric generators, such as thermocouples or thermopiles, the thermoelectric generator 108 herein has a configuration which itself assists in generating a temperature gradient from the heated end to the cooled end.

While the heated end of the thermoelectric generator 108 is heated by the solar concentrator 104, the cooled end may be cooled by a cooling mechanism 148. This allows the beneficial temperature gradient to be created. In general, the cooling mechanism 148 takes heat away from the cooled end of the thermoelectric generator 108 to cool the cool end. This may be accomplished in various ways, now known or later developed. For example, as shown, the cooling mechanism 148 comprises a heat exchanger 112 which transfers heat away from the cool end of the thermoelectric generator 108 and a heat dissipater 116 which dissipates the transferred heat, such as into the environment. To illustrate, the cooling mechanism 148 of this embodiment may transfer heat away from the thermoelectric generator 108 with a heat exchanger 112 and dissipate it through a heat dissipater 116 such as a cooling tower, geothermal heat sink, or the like.

Electricity generated from the thermoelectric generator 108 via the temperature gradient discussed above, may then be used for various purposes or stored for later use. For example, the electricity may be used to power one or more devices or may be stored by batteries or other energy storage devices. It is contemplated that at least some of the electricity may be used to power one or more components of the thermoelectric collector 144. For example, some electricity may be used to power the cooling mechanism 148 in one or more embodiments.

In the embodiment shown, the electricity is used to generate hydrogen. The hydrogen may then be stored for later use in generating energy. Of course, the hydrogen may also be used for other purposes. In this manner, the energy from the sun is collected and captured. The energy from the sun may then be used as desired even when solar energy is not directly available from the sun, such as at night or in bad weather.

As shown, the electricity from the thermoelectric generator 108 is used to power a positive electrode 132 and a negative electrode 136 within a water tank 152 holding a quantity of water. This causes the liquid dihydrogen oxide to be separated into hydrogen and oxygen is gaseous from in an electrolytic process. The hydrogen gas may then be collected from the water tank 152 through one or more conduits 140. The collected hydrogen gas may be stored in a hydrogen storage tank 128 for later use. It is noted that the hydrogen may also be compressed by a compressor 120 to allow a larger quantity of the gas to be stored within the storage tank. Likewise, as illustrated in FIG. 1, oxygen gas from the electrolytic process may also be captured in an oxygen storage tank 124 in a similar fashion. The storage tanks may be a variety of containers suitable for storing gas. This includes underground and aboveground storage containers.

It is contemplated that the hydrogen may be kept in the hydrogen storage tank 128 and may be used directly from the storage tank in one or more embodiments. Alternatively, or in addition, the hydrogen may be bottled or contained in one or more additional storage tanks which may be transported for use at other locations, or pumped through one or more pipes for use at other locations. Typically, the hydrogen gas will be “burned” to generate energy when desired. Of course, the hydrogen gas may be used for various other purposes requiring hydrogen gas.

As can be seen from the above, the thermoelectric collector 144 collects solar energy for use as electricity or for later storage while taking advantage of the cleanliness and abundance of solar energy. When used to generate electricity for direct or immediate use, the thermoelectric collector 144 provides the benefit of clean energy by converting non-polluting energy from the sun into usable electricity. When used to store solar energy, such as in the form of hydrogen, the thermoelectric collector 144 adds the benefit of allowing solar energy to be used at anytime regardless of whether or not the sun is available.

Typically, the thermoelectric collector 144 will be configured to collect and store solar energy in the form of hydrogen. For example, in some embodiments or circumstances (such as bad weather), the thermoelectric collector 144 may not generate sufficient electricity to be used directly, but may generate sufficient electricity to power electrolysis which, as stated, may be used to store solar energy as hydrogen.

It is contemplated that one or more thermoelectric collectors 144 may by installed in areas exposed to high solar energy or other locations to continuously generate hydrogen when solar energy is available. Though the quantity of hydrogen produced may be relatively small, over time, substantial amounts of hydrogen may be produced. Additional thermoelectric collectors 144 may be installed to increase hydrogen production. It will be understood that as many or as few thermoelectric collectors 144 may be installed to provide for the energy needs of surrounding or remote areas.

The thermoelectric collector 144 is highly advantageous to populations where access to electrical power is limited. For example, a population with limited access to electrical power may only desire hydrogen energy at night to power lighting or other electrical devices. Thus, even where the hydrogen generated is a relatively small quantity, this may be sufficient to supply the electrical needs for a given population. Of course, as stated, additional thermoelectric collectors 144 may be installed to meet higher demands for energy. Of course, the electricity, hydrogen, or both generated by the thermoelectric collector 144 may be used at other times as well.

It is also contemplated that thermoelectric collectors 144, and specifically the hydrogen generated form the collectors, may be used to supplement an existing energy source. This is advantageous in that it may reduce the reliance on energy sources known or thought to be damaging to the environment or unsustainable.

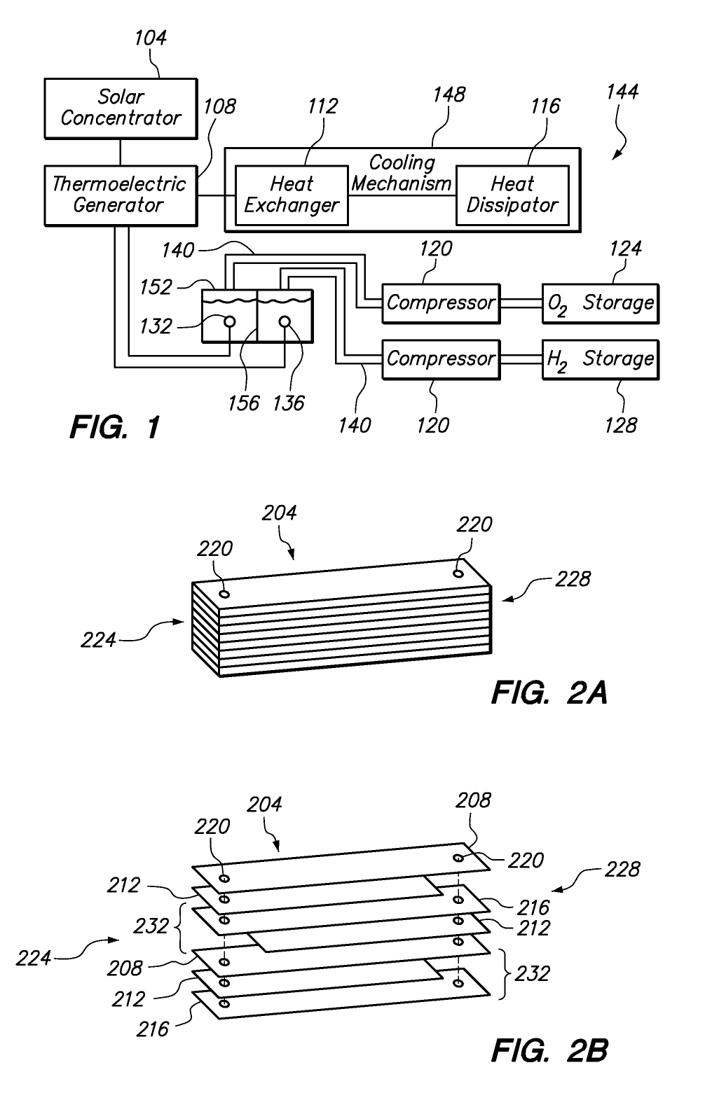

FIGS. 2A-2B illustrate an exemplary thermoelectric generator which may be used with the thermoelectric collector. As shown in the assembled view of FIG. 2A, the thermoelectric generator is a high density thermopile 204 having a heated end 224 and a cooled end 228. In general, the high density thermopile 204 will receive heat at its heated end 224 and dissipate heat at its cooled end 228 to create the temperature gradient used to generate electricity via the thermoelectric effect.

In contrast to traditional thermopiles, which are typically constructed of wire, the high density thermopile 204 has a generally solid mass which maximizes the thermoelectric effect in the volume occupied by the high density thermopile. The solid mass of the high density thermopile 204 also provides large surface area which makes the high density thermopile easier to heat and/or cool. For example, the large surface area allows heat from the sun to be more easily focused on the high density thermopile 204. In addition, the large surface area allows the high density thermopile 204 to dissipate heat as well as to be cooled by a cooling mechanism, as will be described further below.

The high density thermopile 204 may be configured in various ways. In one or more embodiments, the high density thermopile 204 may comprise dissimilar conductive materials and insulating materials. The insulating materials and dissimilar conductive materials may be arranged to form one or more thermocouples where the insulating materials prevent the dissimilar conductive materials from coming into contact along the length of the thermocouples but allow contact of the dissimilar conductive materials at the ends of the thermocouples to form the junctions of the thermocouples.

The dissimilar conductive materials may be various conductive materials. Typically, but not always, the conductive materials will be metals. For example, the conductive materials may be aluminum, copper, steel, iron, various alloys, or other metals. It is noted that various conductive materials, such as metals, may perform differently when used to generate electricity from the thermoelectric effect and that the dissimilar conductive materials may be selected based on their ability to generate electricity from the thermoelectric effect.

In addition, because the thermoelectric collector will typically be used outside, the dissimilar conductive materials, such as metals, may be selected based on their ability to withstand the elements or outdoor use. For example, in some embodiments, the materials may be exposed to allow maximum transfer of heat from the sun. In these embodiments, rust-proof or stainless metals may be used. In other embodiments, it is contemplated that the conductive materials may be covered for protection from the elements such as by one or more coatings or enclosures.

FIG. 2B illustrates an exploded view of an exemplary high density thermopile 204. As shown, the high density thermopile 204 comprises a first conductive material 208, a second conductive material 216, and insulating material 212. As stated, the conductive materials may be various metals. In one embodiment, the first conductive material 208 may be copper and the second conductive material 216 may be constantan. In another embodiment, the first conductive material 208 may be iron and the second conductive material 216 may be copper. In yet another embodiment, the first conductive material 208 may be copper and the second conductive material 216 may be constantan. Of course, various other combinations of metals and/or conductive materials may be used. Likewise, the insulating material 212 may be formed from a variety of one or more electrical insulators.

Thermocouple junctions 232 at the heated end 224 and the cooled end 228 of the high density thermopile 204 are formed by the arrangement of the first conductive material 208, second conductive material 216 and insulating material 212. The insulating material 212 separates the first conductive material 208 and the second conductive material 216 such that electricity is only conducted at the junctions of the first conductive material 208 and the second conductive material. In one or more embodiments, such as shown, these junctions will be located at the heated end 224 and the cooled end 228 of the high density thermopile 204.

As can be seen from the exploded view of FIG. 2B, the insulating materials 212 are shorter in length than the conductive materials 208,216. This allows an electrical connection between the conductive materials 208,216 to be made where the insulating materials 212 do not prevent such a connection. The insulating materials 212 may be staggered, such as shown, to allow electrical connections on alternating ends of the high density thermopile. These electrical connections form the thermocouple junctions 232 at the heated end 224 and cooled end 228 which allow electricity to be generated through the thermoelectric effect.

Though illustrated with a particular number of conductive materials 208,216 and insulating materials 212, it will be understood that a high density thermopile 204 may be constructed from more or fewer of such materials. This is another advantage of the high density thermopile 204. The capacity of the high density thermopile 204 to generate electricity from heat may be adjusted by removing or adding the conductive materials 208 and insulating materials 212.

It is contemplated that a conductive plate or compound may be placed at each thermocouple junction 232 to ensure conductivity between the conductive materials 208, 216 at the junction. For example, a conductive compound such as, but not limited to, graphite may be placed between conductive materials 208,216 at a thermocouple junction 232. The conductive plate or compound provides the benefit of ensuring conductivity at the junction. Also, the conductive plate or compound may have a thickness similar to or the same as the insulating materials 212. This prevents the conductive materials 208,216 from bending to form an electrical connection. Of course, a conductive plate or compound is not required in all embodiments.

The conductive materials 208,216 and insulating materials 212 may be shaped as planar sheets or plates of various thicknesses. In one embodiment for example, the conductive materials 208,216 may be between 0.01 in and 0.02 in thick. Typically, but not always, the conductive materials 208, 216 will have a similar shape and size. Though illustrated in a particular size, it will be understood that the conductive materials 208,216 and insulating materials 212 may be various sizes. For example, the conductive materials 208,216 and insulating materials 212 may have a longer length to increase the distance between the heated end 224 and the cooled end 228 of the high density thermopile 204. This is advantageous in that the longer length may allow various types of cooling mechanisms to be used. Of course, a shorter length may be used in one or more embodiments as well. It is contemplated that the insulating materials 212 may comprise a coating applied to one or more of the conductive materials 208,216 in some embodiments.

It is contemplated that the conductive materials 208,216 may be dimensioned according to the particular material or materials which make up the conductive materials. For example, the conductive materials 208,216 may be dimensioned to provide a particular voltage and/or current output. Conductive materials 208,216 may also or alternatively be dimensioned to provide a particular resistance. To illustrate, the resistance formula

$$R = \frac{ρ \cdot l}{A}$$

(where R is resistance, ρ is resistivity of the material, l is length of the material, and A is the cross-sectional area of the material), may be used to dimension a conductive material 208,216 to provide a desired resistance. It is noted that the configuration of the high density thermopile's conductive materials 208,216 may take into account their internal resistance. Thus, the designed output voltage/current may be higher than that required for electrolysis to occur to compensate for the internal resistance of the conductive materials 208,216. To illustrate, the designed output voltage may be approximately 3 v to produce approximately 1.5 v for electrolysis after internal resistance is taken into account.

In one or more embodiments, the materials making up the high density thermopile 204 may be arranged in a stack such as shown in FIGS. 2A-2B. The stack may be held together to form an assembled high density thermopile 204 in various ways. For example, one or more straps or the like may be wrapped around the high density thermopile 204. In one embodiment, the stack of materials may be placed in an enclosure to hold the materials together. It is contemplated that the materials may be pressed together as well. This ensures that electrical contact between conductive materials 208,216 of the stack may be made (where appropriate) to form the thermocouple junctions 232. It is contemplated also that the materials of the high density thermopile 204 may be adhered, welded, or otherwise secured together as well.

In some embodiments, the conductive materials 208,216 and insulating materials 212 may include one or more openings 220. The openings 220 may be positioned to align when the high density thermopile 204 is assembled. This allows one or more fasteners to be placed in and/or through the openings 220 to secure the conductive materials 208,216 and insulating materials 212 together. It is contemplated that the fasteners may be configured to apply pressure to clamp the conductive materials 208,216 and insulating materials together. In this manner, the fasters help to ensure that the conductive materials 208,216 remain in contact at the thermopile junctions. In one or more embodiments, the fasteners may be formed from non-conductive materials. This prevents unwanted electrical connections from being created by the fasteners.

The fasteners may be removable as well. For example, the fasteners may be threaded such as nuts, bolts, screws, and the like. This is advantageous in that additional conductive materials 208,216 and/or insulating materials 212 may be added to increase the electrical generating capacity of the high density thermopile 204. In addition, conductive materials 208,216 and or insulating materials 212 may be removed to reduce the size and capacity of the high density thermopile 204. Removable fasteners also allow one or more materials of the high density thermopile 204 to be removed and replaced if damaged or destroyed.

The openings 220 may be at the ends of the high density thermopile 204 in one or more embodiments. In these embodiments, one or more fasteners, when placed into the openings may help ensure electrical contact at the thermocouple junctions 232. To illustrate, one or more fasteners may secure portions of the conductive materials 208,216 together such that an electrical connection is made and a thermocouple junction 232 formed.

It is contemplated that the openings 220 may be at various other locations as well. For example, one or more openings 220 may be between the ends of the high density thermopile 204. This allows additional fasteners to be used to secure the conductive materials 208,216 and insulating materials 212 of the high density thermopile 204 together. This is advantageous in that it ensures the materials are held together even in high density thermopiles 204 having longer lengths.

As can be seen from FIGS. 2A and 2B, when assembled, the arrangement of the conductive materials 208,216 and insulating materials 212 form a high density thermopile 204 comprising a plurality of thermocouples. A series of thermocouple junctions 232 are also formed at the heated end 224 and the cooled end 228 of the high density thermopile 204. This allows electricity to be generated via the thermoelectric effect through a temperature gradient between the heated end 224 and the cooled end 228.

In addition, when assembled, the high density thermopile 204 has a generally solid structure which lends itself to heat transfer. As discussed above, this is advantageous in both heating and cooling the high density thermopile. Consequently, the high density thermopile 204 is ideally suited to take advantage of the thermoelectric effect.

An exemplary high density thermopile 204 will now be described to illustrate the output capabilities of the high density thermopile. The exemplary high density thermopile 204 comprises a first conductive material 208 of copper, and a second conductive material 216 of constantan. In addition, the exemplary high density thermopile 204 has a particular number of junctions and a particular size. It will be understood however that the following disclosure/calculations may be applied to a variety of high density thermopiles 204.

A section or layer of the copper conductive material 208 may be 2 in×0.01 in×10 in, while a section or layer of the constantan conductive material 216 may be 2 in×0.02 in×10 in. In the exemplary high density thermopile 204, 160 thermopile junctions 232 may be formed giving the copper conductive material 208 a total length of 1600 in and the constantan conductive material 216 a total length of 1600 in. With the above values and a resistivity p for copper and constantan the resistance of the conductive materials 208,216 may be determined.

For example, assuming a resistivity ρ for copper of 1.68·10⁻⁸ and a ρ for constantan of 49·10⁻⁸ the resistance formula,

$$R = \frac{ρ \cdot l}{A} ,$$

yields a resistance R=0.0529Ω for copper and R=0.7717Ω for constantan. To illustrate, (first converting from inches to meters), the resistance formula yields

$$\frac{1.68 \cdot {10}^{- 8} Ω m \cdot 40.64 m}{2.54 \cdot {10}^{- 4} m \cdot 0.508 m} = 0.0529 Ω$$

for copper, while the resistance formula yields

$$\frac{49 \cdot {10}^{- 8} Ω m \cdot 40.64 m}{5.08 \cdot {10}^{- 4} m \cdot 0.508 m} = 0.7717 Ω$$

for constantan. Accordingly, total resistance of the high density thermopile 204 is 0.7717 Ω+0.05295 Ω=0.82465Ω. It is noted that the resistance at the thermopile junctions 232 may, if desired, be taken into account in determining high density thermopile 204 output.

As stated, a high density thermopile 204 may be used to power electrolysis, such as to generate hydrogen. Assuming electrolysis occurs at approximately 1.5 v, the current available from the high density thermopile 204 to produce electrolysis is approximately 1.82 A. To illustrate, using Ohm's Law,

$$I = \frac{V}{R}$$

(where I is current, V is voltage and R is resistance),

$$\frac{1.5 v}{0.8246 Ω} = 1.82 A .$$

Assuming an available gas volume of 0.627 LPH/A, the exemplary high density thermopile 204 at 1.82 A would produce 1.14 L of gas per hour.

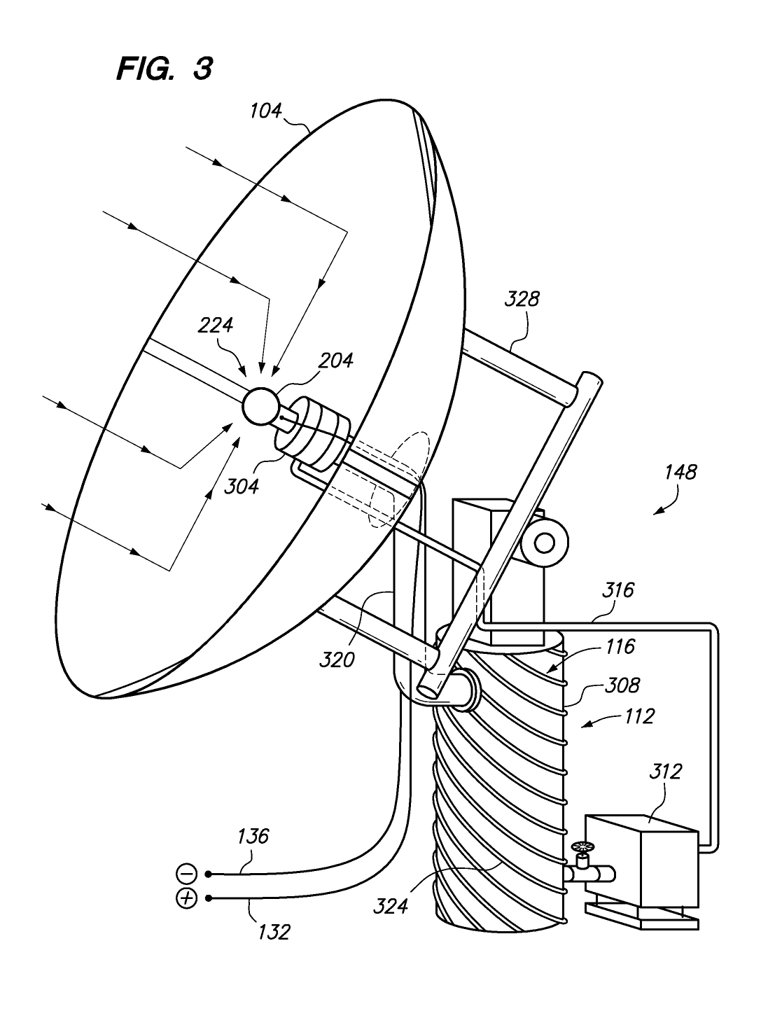

FIG. 3 illustrates an exemplary apparatus which may be used with a high density thermopile 204 to generate electricity via the thermoelectric effect. In general, the apparatus heats one end of the high density thermopile 204 while cooling another end of the thermopile to create a temperature gradient along the thermopile. As shown in FIG. 3, the apparatus includes a solar concentrator 104 in the form of a parabolic dish, a high density thermopile 204, and a cooling mechanism 148.

The solar concentrator 104 is configured to focus the sun's energy on the high density thermopile 204. The solar concentrator 104 may be mounted to a support 328 which secures the concentrator at a position suited to receive energy from the sun. It is contemplated that the support 328 may be rotatable to track the sun ensuring that substantial amounts of the sun's energy are collected by the solar concentrator 104. The support 328 may be motorized and/or automated to automatically track the sun in one or more embodiments.

As can be seen, the high density thermopile 204 may be positioned at a central location relative to the parabolic dish of the solar concentrator 104. In this manner, the sun's energy may be focused on the heated end of the high density thermopile 204. Of course, the high density thermopile 204 may be positioned at other locations. For example, the high density thermopile 204 may be positioned such that its heated end is wherever the solar concentrator 104 focuses the sun's energy.

The high density thermopile 204 may also be shaped to better absorb heat energy provided by the solar concentrator 104. For example, as shown, the heated end of the high density thermopile 204 is bulb shaped. This provides additional surface area to absorb heat provided by the solar concentrator 104. This is advantageous such as where the solar concentrator 104 cannot tightly focus heat energy on a high density thermopile 204 with a smaller surface area.

In one embodiment, the bulb shape may be formed by shaping the conductive and insulating materials of the high density thermopile 204 with the desired shape. It will be understood that various other shapes may be used as well. Alternatively, or in addition, the high density thermopile 204 may be fitted with a bulb or other shaped cover which provides the larger surface area for collecting heat energy. This cover may be formed from material that efficiently transfers heat, such as one or more metals.

One or more electrical leads may be connected to the high density thermopile 204 to allow electricity generated by the thermopile to be transferred to generate hydrogen or for other uses. As shown, a positive lead 136 and a negative lead 132 are connected to the high density thermopile 204. As stated above, electricity form the high density thermopile 204 may be used to power electrolysis to generate hydrogen. In addition, the electricity may be used to power portions of the thermoelectric collector, such as a motor or other device for moving the support 328, or a pump 312 of the thermoelectric collector. Of course, the generated electricity may be used for other purposes as well.

While the heated end of the high density thermopile 204 is heated by the solar concentrator 104, the cooled end of the high density thermopile is preferably cooled by a cooling mechanism 148. In the apparatus of FIG. 3, the cooling mechanism 148 utilizes water to cool the high density thermopile 204. More specifically, water flows over the cooled end of the high density thermopile 204 absorbing heat from the thermopile and thus cooling the cooled end of the thermopile. The water itself is then cooled and then recirculated back to the high density thermopile 204 to absorb heat from the thermopile once again. This water flow may be accomplished in various ways.

As shown, the cooling mechanism 148 utilizes a quench ring 304 into which at least the cooled end of the high density thermopile 204 is inserted. Water from a supply line 316 may be emitted or dispensed from the quench ring 304 such that the water comes into contact with the high density thermopile 204, cooling the thermopile. The water then flows through a return line 320 to a heat exchanger 112 which cools the water by absorbing heat from the water. The heat exchanger 112 may be a water reservoir 308 which absorbs heat from the water.

One or more heat dissipaters 116 may then be used to remove or dissipate heat from the heat exchanger 112 to allow the heat exchanger 112 to continue to absorb heat from the water. Typically, but not always, the heat dissipaters 116 will dissipate heat to the environment. In the embodiment of FIG. 3, the heat dissipaters 116 comprise one or more cooling fins 324 which provide increased surface area allowing heat to be dissipated into the surrounding air.

The cooling mechanism 148 may also comprise a pump 312 and supply line 316 for the quench ring 304. In one or more embodiments, the pump 312 may be attached to the heat exchanger 112 and the supply line 316. Water cooled by the heat exchanger 112 water may be pumped by the pump 312 back to the quench ring 304 through the supply line 316. In this manner, the water used for cooling the high density thermopile 204 is recirculated and not wasted. It is contemplated that water may not be recirculated in some embodiments as city, well, lake, ocean, or other water may be pumped to the quench ring 304. In these embodiments, a heat exchanger 112 and heat dissipater 116 may not be required, though they may be used to cool the water before it is returned to its source to reduce heat pollution. It is noted that the supply of cooling water may be replenished if low from various water supplies. It is also noted that other fluids or coolants besides water may be used with the cooling system 148 to cool the high density thermopile 204.

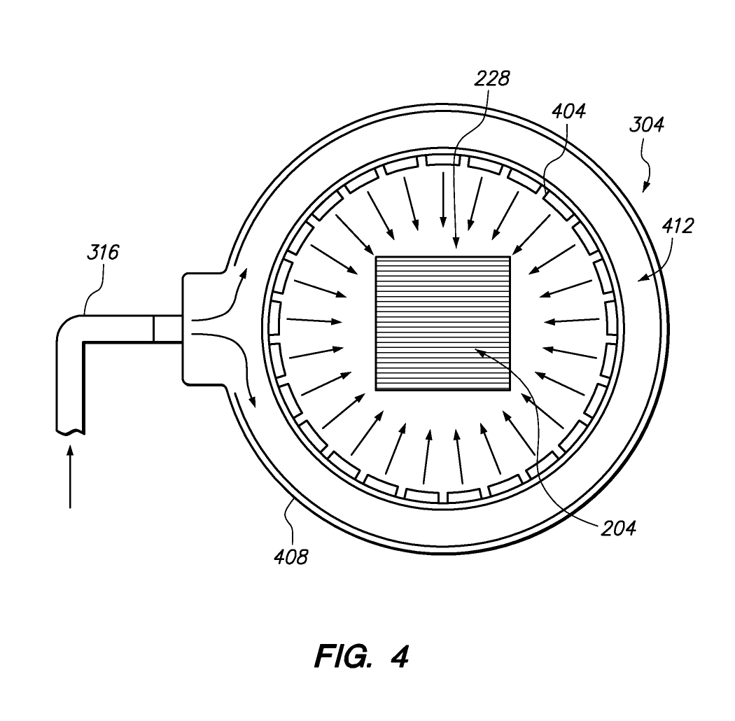

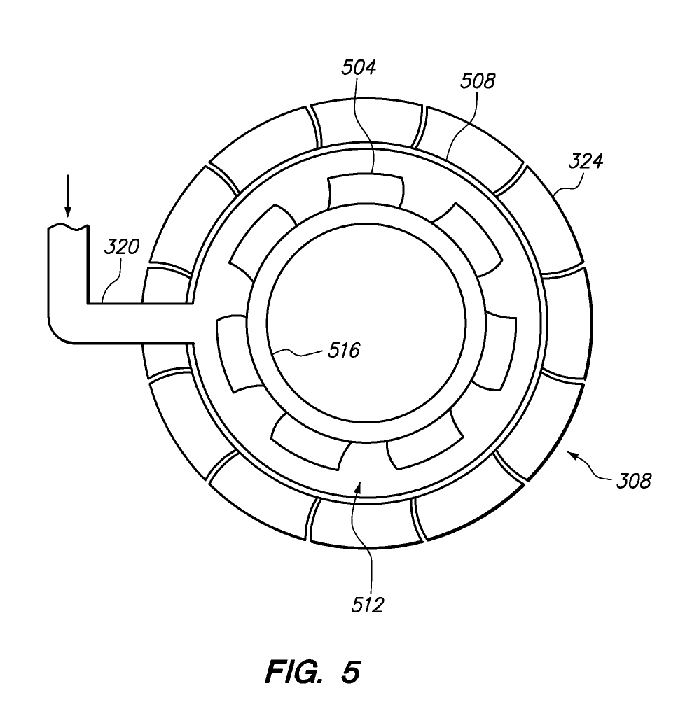

FIG. 4 is a top view illustrating an exemplary quench ring 304. The heated end of a high density thermopile 204 is inserted or located in the quench ring 304. As shown, the quench ring 304 comprises a channel 412 in fluid communication with one or more nozzles 404 on the interior surface of the quench ring. As can be seen, water from the supply line 316 may enter the channel 412 and be distributed onto a high density thermopile 204 by the one or more nozzles 404. Water from the supply line 316 may be under pressure to give the water sufficient velocity out of the nozzles 404 to reach the high density thermopile 204 in one or more embodiments. Referring back to FIG. 3, after cooling the high density thermopile 204, the water may then flow from the quench ring 304 to the return line 320 to be cooled and/or recirculated by the remainder of the cooling mechanism 148 such as described above.

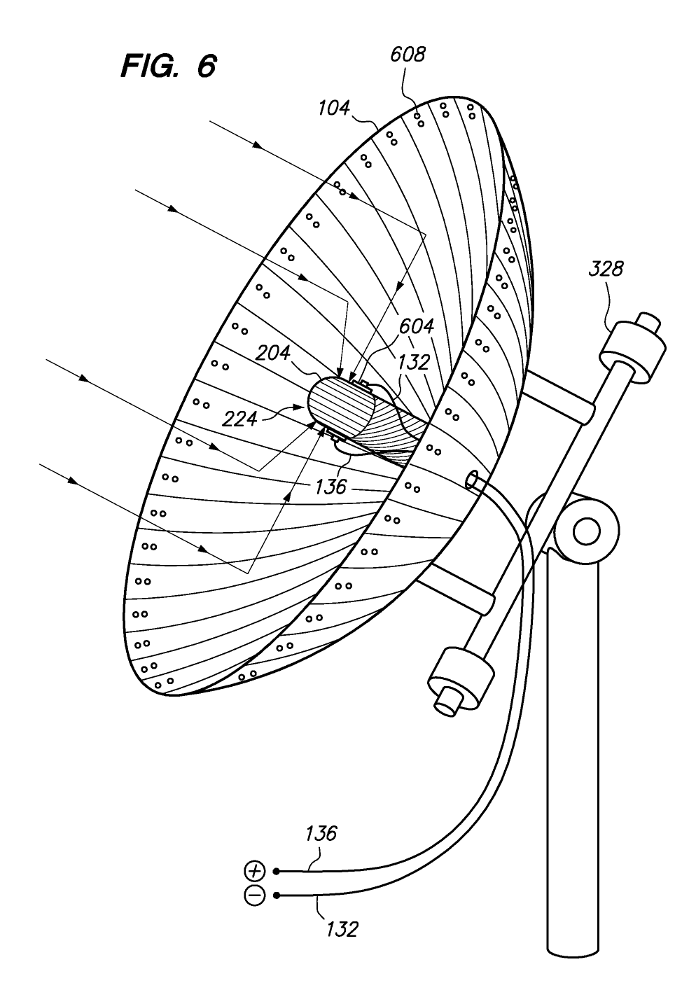

FIG. 5 is a top view of a water reservoir 308. The water reservoir 308 has an outer wall 508 defining an interior space. One or more cooling fins 324 are located at an exterior of the outer wall 508. As shown, the water reservoir 308 also includes an inner core 516 comprising one or more deflectors 504. The inner core 516 is located within the interior space and forms a space or void 512 for water flow between the inner core 516 and outer wall 508 of the water reservoir. The water reservoir 308 may accept water from the return line 320 through its outer wall 508. This water may be deflected by the one or more deflectors 504 toward the outer wall 508. Heat from the water is then transferred to the outer wall 508 and ultimately dissipated by the cooling fins 342 to the environment.

The deflectors 504 may be shaped and/or positioned to deflect water onto the outer wall 508. For example, the deflectors 504 may be curved and/or angled to deflect water flows in this manner. The deflectors 504 may be arranged in a spiral pattern moving up (or down) the length of the inner core 516 in some embodiments. In one embodiment, the inner core 512 may rotate or spin to move the deflectors 504. Water flows may then be deflected onto the outer wall 508 by the centrifugal motion of the deflectors 504.

Though shown with a particular configuration, it is noted that the inner core 516 and deflectors 504 may be configured in various ways. For example, the inner core 516 may be sized to reduce the area of the void 512 between the inner core and outer wall 508. This is advantageous in that it helps ensure that water from the return line 520 comes into contact with the outer wall 508. In addition, or alternatively, the deflectors 508 may extend closer to the outer wall 508 or even contact the outer wall 508 to ensure water contact with the outer wall. In one embodiment, the deflectors 508 may form a spiral (like the threads of a screw) to allow constant or near constant water contact with the outer wall 508 as water flows along the spiral through the water reservoir 308. This allows the water to be effectively cooled by the water reservoir 308 and cooling fins 324.

In some embodiments, the high density thermopile 204 may be allowed to cool itself For example, the heated end may be heated by a device or apparatus while the cooled end is allowed to dissipate heat without the assistance of any device or apparatus.

FIG. 6 illustrates an embodiment where the high density thermopile 204 is configured to cool itself. This is advantageous in that the number of components of a thermoelectric collector may be reduced thus reducing expense and potentially increasing reliability. In addition, self cooling generally does not utilize a power source and thus has a higher energy efficiency.

As can be seen, the apparatus of FIG. 6 utilizes a parabolic dish as a solar concentrator 104. In this embodiment, the parabolic dish focuses heat energy from the sun onto the heated end of a high density thermopile 204. Similar to the above apparatus, the solar concentrator 104 may be mounted to a support 328. The support 328 allows the solar concentrator 104 to be oriented to receive heat energy from the sun. In addition, as described above, the support 328 may rotate or move to track the sun.

In one or more embodiments, the high density thermopile 204 may be configured to form the solar collector 104. As can be seen from FIG. 6, the materials forming the high density thermopile 204 may twist and fan outward while curving to form the parabolic shape of the solar collector 104. In this manner, the heated end 224 of the high density thermopile 204 is positioned at a central location of the solar collector 104 to absorb the heat energy focused by the solar collector. The cooled end 228 of the high density thermopile 204 is remote from the heated end 224 to allow a temperature gradient between the heated end and the cooled end. In one or more embodiments, the cooled end 228 of the high density thermopile 204 may be the outer rim or edge of the solar collector 104, such as shown.

The cooled end 228 of the high density thermopile 204 may function as its own cooling mechanism by allowing heat absorbed by the heated end 224 to dissipate into the surrounding environment. In one or more embodiments, one or more holes 608 may be formed at the cooled end 228 of the high density thermopile 204 to aid in dissipating heat by allowing air flow to carry away heat. In this way, the one or more holes 608 may function as heat dissipaters.

It is noted that the cooled end 228 may also be cooled in other ways. For example, a flow of water or other coolant may be provided by one or more conduits running along the cooled end 228. The coolant may absorb heat from the cooled end to cool the cooled end 228. The cooling mechanism described above as well as other cooling mechanisms may be used as well.

As stated above, materials of the high density thermopile 204 may be secured together by one or more fasteners. In the embodiment of FIG. 6 one or more fasteners 604 may be used to secure the heated end, cooled end, or both ends of the high density thermopile 204. In addition, one or more electrical leads may be attached to the high density thermopile 204 to allow the electricity generated by the thermopile to be transferred from the thermopile for generation of hydrogen or other uses. For instance, in the embodiment shown, a positive lead 136 and a negative lead 132 are connected to the high density thermopile 204.

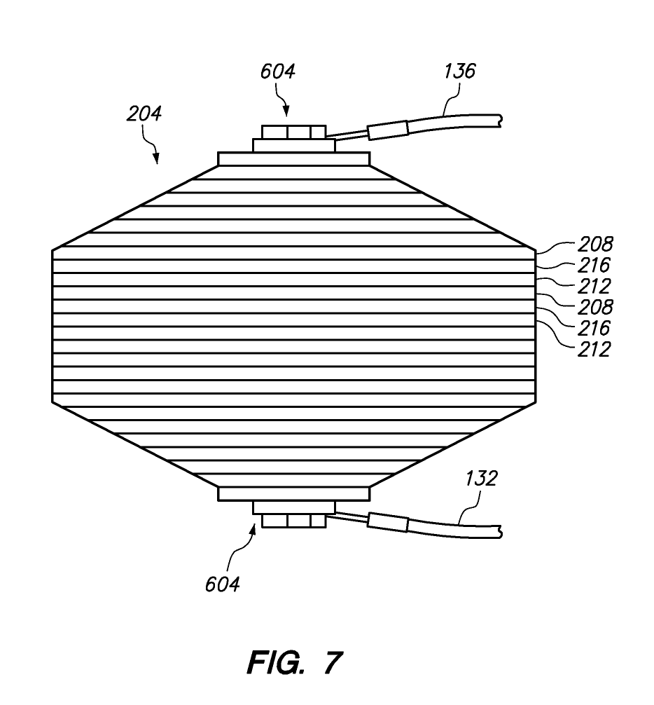

FIG. 7 is a top view of the high density thermopile 204 having a positive lead 136 and a negative lead 132 connected thereto. The high density thermopile 204 may be held or secured together by one or more fasteners 604, such as shown. As can be seen, the heated end of the high density thermopile 204 may be shaped in various ways. In this manner, a bulb-like shape for the heated end (such as shown in FIGS. 3 and 6) of the high density thermopile 204 may be formed. It is noted that the cooled end may be shaped as well in one or more embodiments.

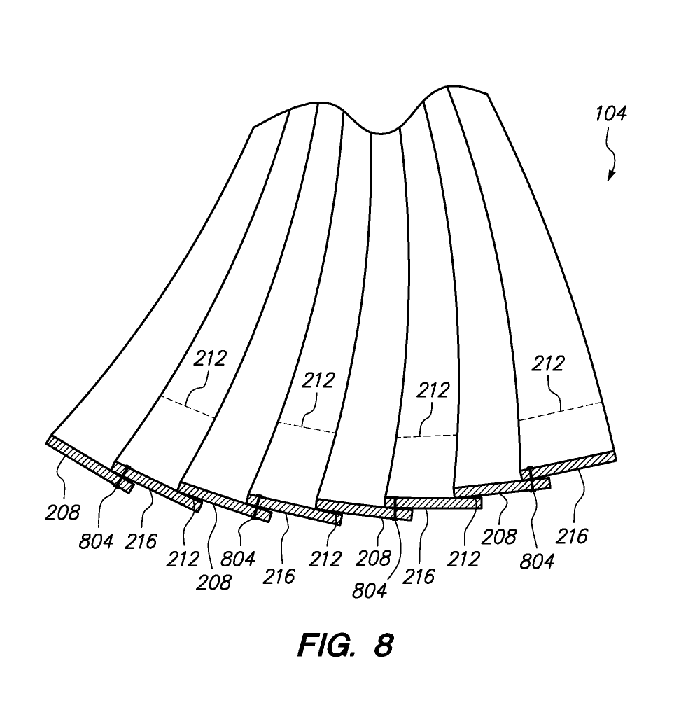

As can be seen, the high density thermopile 204 comprises dissimilar conductive materials 208,216 and insulating materials 212 arranged to form the high density thermopile. FIG. 8 is a perspective view of a portion of the parabolic dish formed by the high density thermopile 204. As can be seen, the conductive materials 208,216 may fan apart and curve to form the parabolic surface of the solar collector 104. One or more additional fasteners 604 may be used to secure the materials of the high density thermopile 204 together. As shown in FIG. 7, the fasteners 604 have been installed at the thermopile junctions 232 to ensure electrical contact between the conductive materials 208,216. Of course fasteners 604 may be installed at other locations as well. As stated above, the fasteners 604 may be nonconductive in one or more embodiments and may be removable as well. In one embodiment the fasteners 604 may be screws, nuts, bolts, pins, clamps, clips, or the like. The fasteners 604 may also be welds or crimps as well.

Similar to the high density thermopile 204 of FIGS. 2A-2B, insulating material 212 may be arranged within the high density thermopile to allow electrical contact between the conductive materials 208,216 at the thermocouple junctions 232 but not along the length of the conductive materials. Referring back to FIG. 8, it can be seen that the insulating materials 212 may be staggered to form thermocouple junctions 232 on alternating ends of the high density thermopile 204. To illustrate, the insulating material 212 between the first pair of conductive materials 208,216 may be configured to not extend to the end of the conductive materials to form a thermocouple junction 232 between the conductive materials 208,216. The next insulating material 212 (shown to the right of the leftmost insulating material in FIG. 8), may extend to the ends of the conductive materials 208,216. In this manner, thermocouple junctions 232 on alternating ends of the high density thermopile 204 may be formed.

The fanning out of the high density thermopile 204 as it reaches the cooled end 228 not only forms the parabolic dish of the solar concentrator 104, but also provides increased surface area which aides in heat dissipation and improves cooling. The portions of the conductive materials 208,216 which form the surface of the parabolic dish may be treated so as to better reflect heat energy towards the heated end of the high density thermopile 204.

For example, the conductive materials 208,216 may be polished to have a reflective or shiny surface. Alternatively or in addition, the conductive materials 208, 216 may be coated or covered with heat reflective materials or coverings. For example, a parabolic reflective covering may be used. Though the sun's heat may heat the cooled end 228 to a certain extent, it is noted that the cooled end will be cool relative to the heated end 224 thus generating the temperature gradient required to generate electricity through the thermoelectric effect.

It is noted that though shown with particular apparatus, the high density thermopile may be used with other devices or apparatus as well. In general, the high density thermopile may be used with any heat generating and/or heat concentrating device or apparatus as long as sufficient heat is provided to the heated end of the thermopile to generate electricity via the thermoelectric effect. Likewise the high density thermopile may be cooled by dissipating heat itself or by various cooling mechanisms.

While various embodiments of the invention have been described, it will be apparent to those of ordinary skill in the art that many more embodiments and implementations are possible that are within the scope of this invention. In addition, the various features, elements, and embodiments described herein may be claimed or combined in any combination or arrangement.

What is claimed is:

1. A thermoelectric collector comprising:
a high density thermopile having a heated end and a cooled end, the high density thermopile comprising one or more planar dissimilar conductive materials and one or more planar insulating materials arranged in a stack to form a solid body of the high density thermopile whereby the one or more planar insulating materials are staggered to form one or more electrical junctions at least one end of the high density thermopile;
a solar concentrator configured to direct heat from the sun on the heated end of the high density thermopile;
a cooling mechanism configured to transfer heat away from the cooled end of the high density thermopile with one or more coolants; and
one or more electrical leads connected to one or more of the one or more conductive materials, wherein electricity generated by the high density thermopile travels away from the high density thermopile via the one or more electrical leads.

2. The thermoelectric collector of claim 1 further comprising one or more fasteners, wherein the one or more fasteners secure the one or more planar dissimilar conductive materials and one or more planar insulating materials at the heated end and the cooled end to form the one or more electrical junctions.

3. The thermoelectric collector of claim 1, wherein the solar collector comprises a curved surface configured to reflect the heat from the sun on the heated end of the high density thermopile.

4. The thermoelectric collector of claim 1, wherein the cooling mechanism comprises a heat exchanger configured to transfer heat from the cooled end of the high density thermopile.

5. The thermoelectric collector of claim 1, wherein the cooling mechanism comprises:
a quench ring at the cooled end of the high density thermopile configured to cool the cooled end with one or more coolants; and
a heat exchanger configured to receive the one or more coolants from the quench ring, wherein the heat exchanger absorbs heat from the one or more coolants.

6. The thermoelectric collector of claim 5 wherein the heat exchanger comprises:
an outer wall;
one or more deflectors on an inner surface of the heat exchanger, the one or more deflectors configured to direct the one or more coolants toward the outer wall to transfer heat from the one or more coolants to the heat exchanger; and
one or more cooling fins on the outer wall, the one or more cooling fins configured to dissipate heat from the outer wall.

7. The thermoelectric collector of claim 1 further comprising an electrolysis tank configured to generate hydrogen through electrolysis, the electrolysis tank powered by electricity from the one or more electrical leads.

8. A thermoelectric collector comprising:
a high density thermopile having a heated end and a cooled end, the high density thermopile comprising one or more dissimilar conductive materials and one or more insulating materials arranged in a stack to form a solid body of the high density thermopile whereby the one or more insulating materials are staggered to form one or more electrical junctions at least one end of the high density thermopile;
a parabolic solar concentrator configured to direct heat from the sun on the heated end of the high density thermopile; and
one or more electrical leads connected to one or more of the one or more dissimilar conductive materials, the one or more electrical leads configured to conduct electricity generated by the high density thermopile.

9. The thermoelectric collector of claim 8 further comprising one or more fasteners, wherein the one or more fasteners secure the one or more dissimilar conductive materials and one or more insulating materials at the heated end and the cooled end to form the one or more electrical junctions.

10. The thermoelectric collector of claim 8 further comprising one or more conductive compounds between the one or more dissimilar conductive materials at the one or more electrical junctions.

11. The thermoelectric collector of claim 8, wherein the cooled end of the high density thermopile has an increased surface area relative to the heated end to cool the cooled end of the high density thermopile.

12. The thermoelectric collector of claim 8, wherein the one or more dissimilar conductive materials of the high density thermopile form the parabolic solar concentrator.

13. The thermoelectric collector of claim 12 further comprising one or more openings at the cooled end of the high density thermopile, wherein the one or more openings help cool the cooled end of the high density thermopile.

14. The thermoelectric collector of claim 8 further comprising a cooling mechanism at the cooled end of the high density thermopile.

15. The thermoelectric collector of claim 8 further comprising an electrolysis tank configured to generate hydrogen through electrolysis, the electrolysis tank powered by electricity from the one or more electrical leads.

16. A method of solar energy collection comprising:
at a high density thermopile having a heated end and a cooled end, the high density thermopile comprising one or more planar dissimilar conductive materials and one or more planar insulating materials arranged in a stack to form a solid body of the high density thermopile whereby the one or more insulating materials are staggered to form one or more electrical junctions at least one end of the high density thermopile:
receiving heat at the heated end of the high density thermopile;
creating a temperature differential between the heated end of the high density thermopile and the cooled end of the high density thermopile; and
generating electricity with the temperature differential between the heated end and the cooled end of the high density thermopile.

17. The method of claim 16 further comprising directing heat from the sun on the heated end of the thermopile with a parabolic solar concentrator.

18. The method of claim 17, wherein the parabolic solar concentrator is comprised of the one or more dissimilar conductive materials whereby the one or more dissimilar conductive materials fan out and curve to form the parabolic solar concentrator.

19. The method of claim 16 further comprising converting the generated electricity to hydrogen through electrolysis.

20. The method of claim 16, wherein a cooling mechanism is used to create the temperature differential between the heated end and cooled end of the high density thermopile, the cooling mechanism comprising:
a quench ring at the cooled end of the high density thermopile configured to cool the cooled end with one or more coolants; and
a heat exchanger configured to receive the one or more coolants from the quench ring, wherein the heat exchanger absorbs heat from the one or more coolants.
